(19) United States
(12) Patent Application Publication
(10) Pub. No.: US 2026/0136922 A1
(43) Pub. Date: May 14, 2026

(54) PACKAGE STRUCTURE AND METHOD OF FORMING THE SAME

(71) Applicant: Taiwan Semiconductor Manufacturing Company, Ltd., Hsinchu (TW)

(72) Inventors: You Ru Lee, Kaohsiung City (TW); Ching Yang Chen, Hsinchu County (TW); Yi Ping Chiang, Hsinchu (TW); Hsin Ying Lin, Hsinchu (TW)

(73) Assignee: Taiwan Semiconductor Manufacturing Company, Ltd., Hsinchu (TW)

(21) Appl. No.: 18/945,471

(22) Filed: Nov. 12, 2024

(51) Int. Cl. H01L 23/522; H01L 21/48; H01L 23/00; H01L 23/552; H01L 23/66; H01L 25/16; H10B 80/00

(52) U.S. Cl. CPC H10W 20/497; H10W 42/20; H10W 44/20; H10W 70/095; H10W 90/00; H10B 80/00; H10W 44/241; H10W 72/01235; H10W 72/01253; H10W 72/252; H10W 72/884; H10W 74/15; H10W 90/724; H10W 90/734; H10W 90/754

(57) ABSTRACT

A package structure includes forming a semiconductor substrate for RF application, a first ultra thick metal disposed over the semiconductor substrate, a second ultra thick metal disposed over the first ultra thick metal, and a bump structure directed formed on the second ultra thick metal. The second ultra thick metal is coupled to the first ultra thick metal. A patterned ground shield (PGS) structure may be formed over the semiconductor substrate and below the first ultra thick metal.

### BACKGROUND

Semiconductor devices and integrated circuits used in a variety of electronic applications, such as cell phones and wearable devices, are typically manufactured on a single semiconductor wafer. The dies of the wafer may be processed and packaged with other semiconductor devices or dies at the wafer level, and various technologies have been developed for the wafer level packaging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of simplified system in package (SiP), in accordance with some embodiments.

FIG. 2 is an exploded view of a radio frequency (RF) chip in accordance with some embodiments.

FIG. 3 is a cross-sectional view of a RF chip in accordance with some embodiments.

FIG. 4 illustrates the variation with respect to die area for different wiring arrangements.

FIG. 5A is a cross-sectional view of a RF chip in accordance with some embodiments.

FIG. 5B is a perspective view of a portion of the RF chip of FIG. 5A in accordance with some embodiments.

FIGS. 6A through 6E are cross-sectional views of a process for the formation of a package structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “on,” “over,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments provide a radio frequency (RF) chip and a method of forming the same which is suitable for sub-6 GHz application; however, other ultra-high frequency (mm-Wave) bands may also be applied such as 28 GHZ, 38 GHz or higher frequencies. Other frequencies are possible and contemplated.

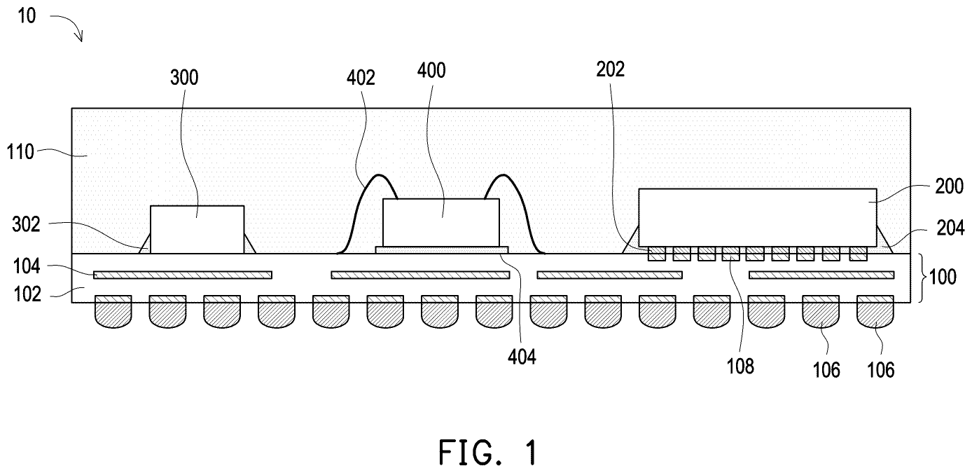

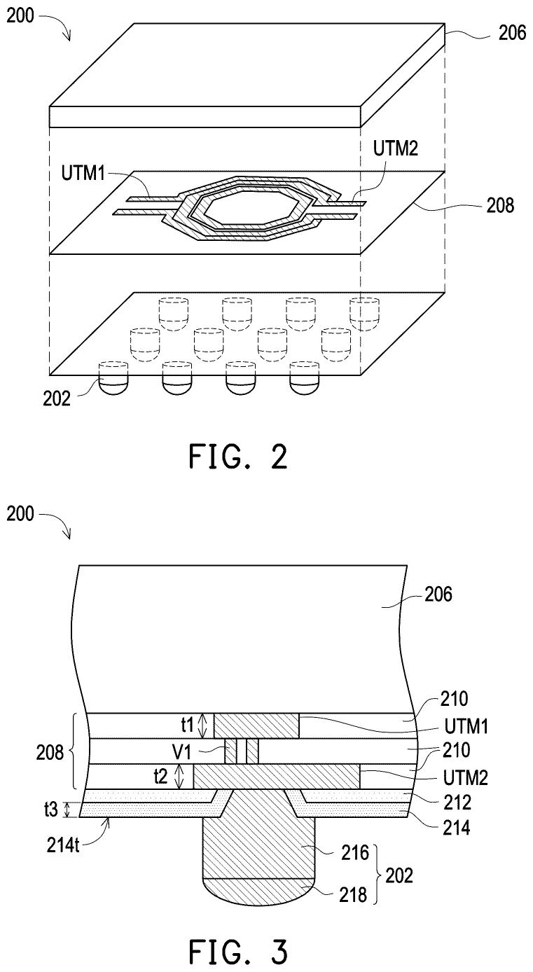

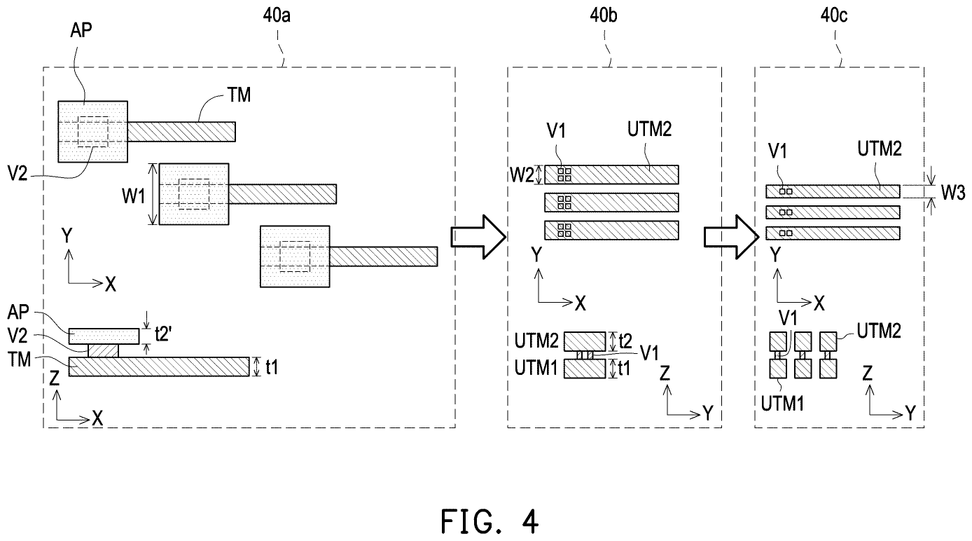

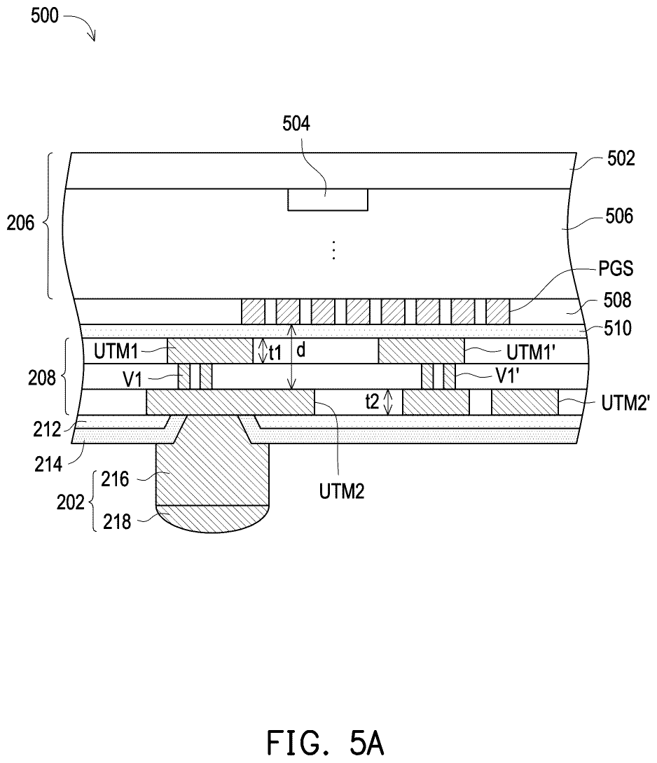

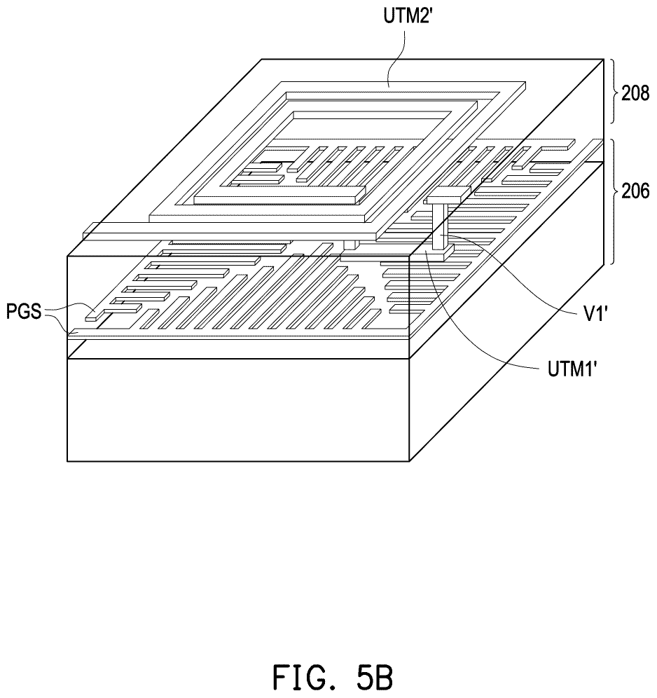

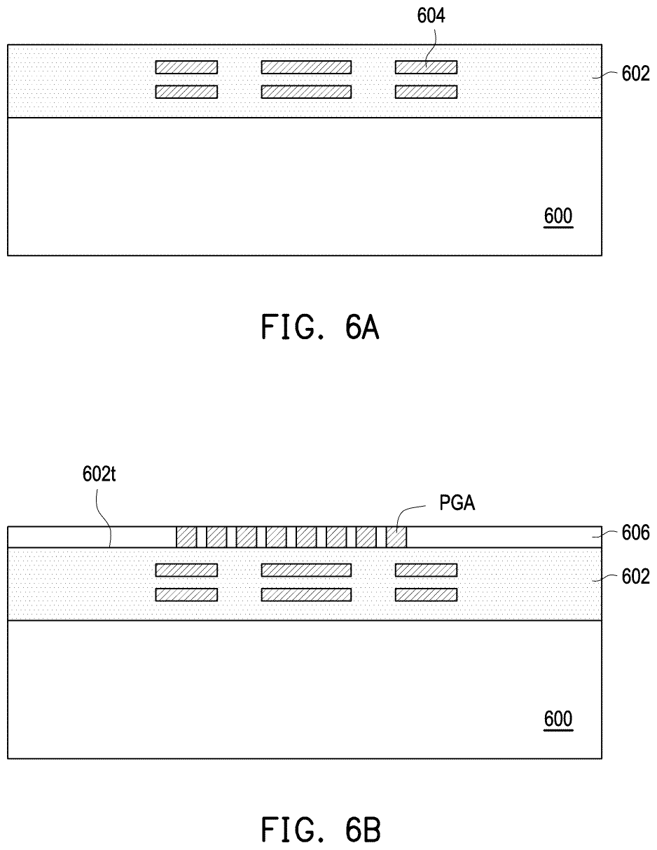

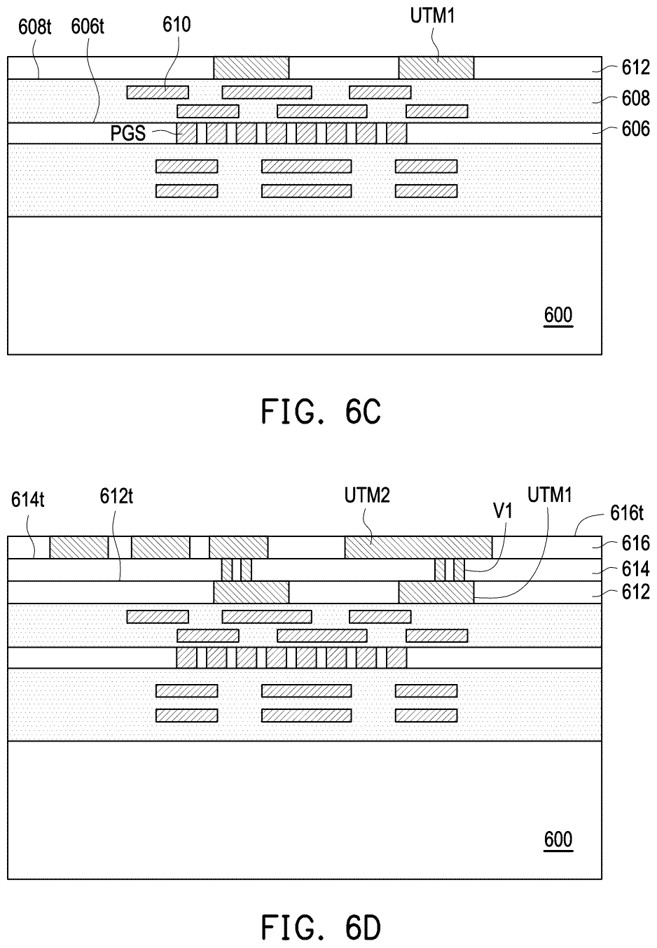

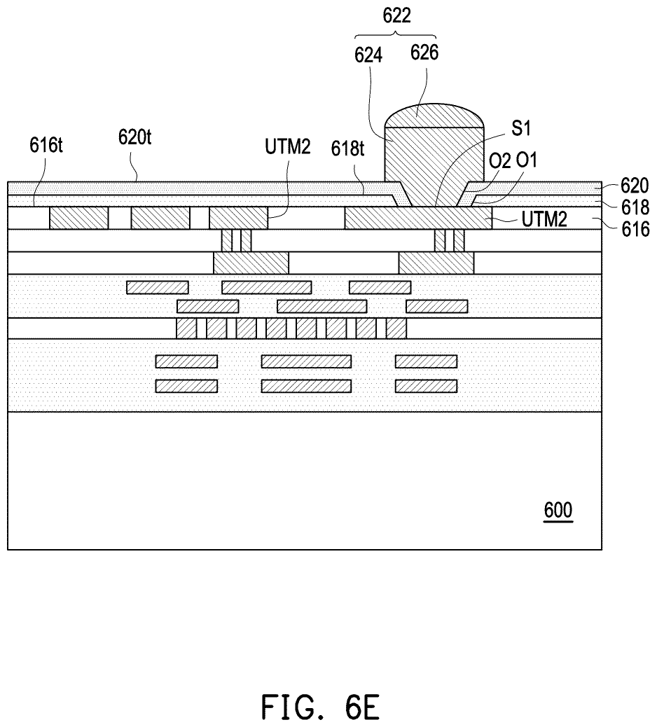

The various aspects of the present disclosure will now be discussed below with reference to FIGS. 1-6E. In more detail, FIG. 1 illustrates an example of simplified system in package (SiP), in accordance with some embodiments of the present disclosure. FIG. 2 is an exploded view of a radio frequency (RF) chip in accordance with some embodiments of the present disclosure. FIG. 3 is a cross-sectional view of a RF chip in accordance with some embodiments of the present disclosure. FIG. 4 illustrates the variation with respect to die area for different wiring arrangements. FIG. 5A is a cross-sectional view of a RF chip in accordance with some embodiments of the present disclosure. FIG. 5B is a perspective view of a portion of the RF chip of FIG. 5A. FIGS. 6A-6E illustrate cross-sectional views of a package structure at various stages of fabrication according to embodiments of the present disclosure.

Embodiments herein may be described in a specific context, namely a system-in-package (SIP) that includes one or more functional semiconductor dies (also called chips) and passive devices integrated on opposite sides of a package substrate. Other embodiments contemplate other applications, such as different package types or different configurations that would be readily apparent to a person of ordinary skill in the art upon reading this disclosure. It should be noted that embodiments discussed herein may not necessarily illustrate every component or feature that may be present in a structure. For example, multiples of a component may be omitted from a figure, such as when discussion of one of the component may be sufficient to convey aspects of the embodiment. Further, method embodiments discussed herein may be discussed as being performed in a particular order; however, other method embodiments may also be performed in any logical order.

Referring now to FIG. 1, a system in package 10 may includes a circuit substrate 100 and several functional semiconductor dies encapsulated by an insulating encapsulant 110 over the circuit substrate 100. The functional semiconductor dies are individual dies singulated from a wafer. In one embodiment, each functional semiconductor die may be a logic device (e.g., central processing unit (CPU), graphics processing unit (GPU), microcontroller, etc.), a memory device (e.g., dynamic random access memory (DRAM) die, static random access memory (SRAM) die, etc.), a power management device (e.g., power management integrated circuit (PMIC) die), a radio frequency (RF) device, a sensor device, a micro-electro-mechanical-system (MEMS) device, a signal processing device (e.g., digital signal processing (DSP) die), a front-end device (e.g., analog front-end (AFE) dies), the like, or a combination thereof (e.g., a system-on-a-chip (SoC) die). For example, a RF chip 200, a surface mount device (SMD) 300 and a memory die 400 are bonded to the circuit substrate 100. In some embodiments, the SMD 300 may be a passive component, such as a resistor, a capacitor, or an inductor, but various embodiments of the present disclosure are not limited in this regard. The number, sizes and types of the functional semiconductor dies disposed on the circuit substrate 100 may be appropriately adjusted based on product requirement.

In some embodiments, the RF chip 200 is mounted or attached onto the circuit substrate 100 through the bump structures 202. In some embodiments, an underfill structure 204 may be formed to fill up the spaces in between the circuit substrate 100 and the RF chip 200. In certain embodiments, the underfill structure 204 fills up the spaces in between adjacent bump structures 202 and covers the bump structures 202. For example, the underfill structure 204 surrounds the bump structures 202. In some embodiments, the underfill structure 204 is formed of an underfill material such as a molding compound, epoxy, or the like. In some embodiments, the circuit substrate 100 includes a plate 102, metallization layers 104, conductive balls 106, contact pads 108, and vias (not shown). In some embodiments, the contact pads 108 are respectively distributed on two opposite sides of the plate 102, and are exposed for electrically connecting with later-formed elements/features. In some embodiments, the metallization layers 104 and the vias are embedded in the plate 102 and together provide routing function for the circuit substrate 100, wherein the metallization layers 104 and the vias are electrically connected to the contact pads 108. In other words, at least some of the contact pads 108 are electrically connected to some of the conductive balls 106 through other contact pads, the metallization layers 104 and the vias. In some embodiments, the contact pads 108 may include metal pads or metal alloy pads. In some embodiments, the materials of the metallization layers 104 and the vias may be substantially the same or similar to the material of the contact pads 108. In some embodiments, the plate 102 is such as an organic flexible substrate or a printed circuit board. In some embodiments, the conductive balls 106 are, for example, solder balls or ball grid array (BGA) balls.

In some embodiments, the insulating encapsulant 110 is formed on the circuit substrate 100. In some embodiments, the insulating encapsulant 110 is formed through, for example, a compression molding process or transfer molding. In one embodiment, a curing process is performed to cure the insulating encapsulant 110. In some embodiments, another underfill structure 302 may be formed to fill up the spaces in between the circuit substrate 100 and the SMD 300. In some embodiments, the underfill structure 302 is formed of an underfill material such as a molding compound, epoxy, or the like. In some embodiments, the RF chip 200, the SMD 300, the memory die 400, the underfill structures 204 and 302, and the wiring 402 for electrical connecting the memory die 400 to the circuit substrate 100 are encapsulated by the insulating encapsulant 110. In some embodiments, a material of the insulating encapsulant 110 includes polymers (such as epoxy resins, phenolic resins, silicon-containing resins, or other suitable resins), dielectric materials having low permittivity (Dk) and low loss tangent (Df) properties, or other suitable materials. In an alternative embodiment, the insulating encapsulant 110 may include an acceptable insulating encapsulation material. In some embodiments, the insulating encapsulant 110 may further include inorganic filler or inorganic compound (e.g. silica, clay, and so on) which can be added therein to optimize coefficient of thermal expansion (CTE) of the insulating encapsulant 110. However, the disclosure is not limited thereto.

In FIG. 2, the RF chip 200 is provided and includes a semiconductor substrate 206, the bump structures 202, and a radio frequency (RF) circuit 208 between the semiconductor substrate 206 and the bump structures 202. The RF circuit 208 includes at least a first ultra thick metal UTM1 and a second ultra thick metal UTM2. The detail of the RF chip 200 is shown in FIG. 3.

In FIG. 3, the first ultra thick metal UTM1 and the second ultra thick metal UTM2 are disposed at different layers, and the first ultra thick metal UTM1 can be coupled to the second ultra thick metal UTM2 through a plurality of vias V1. In some embodiments, at least one of the first ultra thick metal UTM1 and the second ultra thick metal UTM2 forms a portion of an inductor. For example, an inductor in the RF circuit 208 may include an upper metal, a lower metal, and a via connecting the upper metal and the lower metal to form a conductive loop. In some embodiments, the upper metal can be the second ultra thick metal UTM2, the lower metal can be the first ultra thick metal UTM1, and the via can be the plurality of vias V1. In other embodiments, the first ultra thick metal UTM1 and/or the second ultra thick metal UTM2 forms a portion of a power line. In some embodiments, In some embodiments, a thickness t1 of the first ultra thick metal UTM1 is greater than 3 μm, for example, greater than 5 μm or greater than 10 μm. In some embodiments, a thickness t2 of the second ultra thick metal UTM2 is greater than 3 μm, for example, greater than 5 μm or greater than 10 μm. While a thickness range for some embodiments is provided, one skilled in the art will recognize that the appropriate film thickness will depend upon numerous design and performance characteristics.

In some embodiment, a plurality of dielectric layers 210, commonly referred to as an inter-metal dielectric (IMD), is formed over the substrate 206. In some embodiments, each of the dielectric layers 210 is formed of a low k dielectric material such as silicon oxide, silicon nitride, spin-on-glass (“SOG”), TEOS, halogenated SiO, fluorinated silicate glass (“FSG”) or the like, and is deposited by spin-on techniques, electro-chemical plating, chemical vapor deposition (“CVD”), physical vapor deposition (“PVD”), atomic layer deposition (“ALD”), molecular beam epitaxy CVD, and the like. The second ultra thick metal UTM2, the first ultra thick metal UTM1, and the vias V1 may be formed in different dielectric layers 210 respectively.

In an embodiment, the substrate 206 is a semiconductor substrate, such as a silicon substrate, although it may include other semiconductor materials, such as silicon germanium, silicon carbide, gallium arsenide, or the like. Alternatively, the substrate 206 includes a compound semiconductor including gallium phosphide, indium phosphide, indium arsenide, and/or indium antimonide; an alloy semiconductor including GaAsP, AlInAs, AlGaAs, GaInAs, GaInP, and/or GaInAsP; or combinations thereof. In yet another alternative, the substrate 206 is a semiconductor on insulator (SOI). In other alternatives, the substrate 206 may include a doped epi layer, a gradient semiconductor layer, and/or a semiconductor layer overlying another semiconductor layer of a different type, such as a silicon layer on a silicon germanium layer.

Referring to FIG. 3, the bump structure 202 is directly disposed on the second ultra thick metal UTM2. In other words, the bump structure 202 is in direct contact with the second ultra thick metal UTM2. In some embodiments, the bump structure 202 may includes a conductive connector 216. The conductive connector 216 may be ball grid array (BGA) bump structures, solder balls, metal pillars, controlled collapse chip connection (C4) bumps, micro bumps, electroless nickel-electroless palladium-immersion gold technique (ENEPIG) formed bumps, or the like. The conductive connector 216 may include a conductive material such as solder, copper, aluminum, gold, nickel, silver, palladium, tin, the like, or a combination thereof. For example, the conductive connector 216 is a copper bump, and the copper bump is in direct contact with the second ultra thick metal UTM2. The metal pillars may be solder free and have substantially vertical sidewalls. In some embodiments, a metal cap layer 218 is formed on the top of the conductive connector 216. The metal cap layer 218 may include nickel, tin, tin-lead, gold, silver, palladium, indium, nickel-palladium-gold, nickel-gold, the like, or a combination thereof and may be formed by a plating process.

In some embodiments, a passivation layer 212 is disposed on the second ultra thick metal UTM2 to protect the second ultra thick metal UTM2. The passivation layer 212 may be made of a dielectric material. The dielectric material may be made of or include silicon nitride, silicon oxynitride, silicon carbide, one or more other suitable materials, or a combination thereof. The passivation layer 212 may have an opening to expose a portion of the second ultra thick metal UTM2. In some embodiments, a polymer dielectric layer 214 is disposed on the passivation layer 212 over the second ultra thick metal UTM2, wherein a thickness t3 of the polymer dielectric layer 214 is less than the thickness t2 of the second ultra thick metal UTM2. The polymer dielectric layer 214 may be made of or include an organic material. The organic material may include polyimide (PI), polybenzoxazole (PBO), benzocyclobutene (BCB), one or more other suitable materials, or a combination thereof. The organic material may be photosensitive. The bump structure 202 passes through the polymer dielectric layer 214 to connect with the exposed portion of the second ultra thick metal UTM2. Since the thickness t2 of the second ultra thick metal UTM2 may be thick enough to let the polymer dielectric layer 214 having a flat topography, the top surface 214t of the polymer dielectric layer 214 is a flat surface.

FIG. 4 illustrates the variation with respect to die area for different wiring arrangements.

In the box 40a, the upper portion illustrates a top view of a conventional wiring design (i.e. a X-Y plane schematic diagram), and the lower portion illustrates a cross-sectional view of the conventional wiring design (i.e. a X-Z plane schematic diagram). The bump structure in the conventional wiring design is formed directly on an under-bump metallurgies (UBMs) such as aluminum pad AP. Since the thickness t2′ of the Al pad AP is generally thinner than the thickness t2 of the second ultra thick metal UTM2, and the electrical conductivity of aluminum is lower itself, larger area is required for the Al pad AP. For example, the width Wl of the Al pad AP is larger than that of the top metal TM thereunder. The via V2 for connecting the Al pad AP to the top metal TM also become bigger so as to reduce the resistance. When the area of the Al pad AP is required to be larger, the distance from one Al pad AP to another Al pad AP and the distance between the Al pad AP and adjacent top metal TM have to be kept at a safe distance. Accordingly, if three Al pads AP are disposed close, those features will occupy a large area as shown in FIG. 4.

In contrast, in the box 40b, the upper portion illustrates a top view of a wiring design in some embodiments of the disclosure (i.e. a X-Y plane schematic diagram), and the lower portion illustrates a cross-sectional view of the wiring design in some embodiments of the disclosure (i.e. a Y-Z plane schematic diagram). The bump structure of the disclosure is formed directly on the second ultra thick metal UTM2, and the second ultra thick metal UTM2 has a thicker thickness and is usually made of copper which has higher electrical conductivity; therefore, the Al pad AP is replaced by the second ultra thick metal UTM2, the distance between one of the second ultra thick metal UTM2 to another of the second ultra thick metal UTM2 can be reduced significantly, even if the thickness t1 of the top metal TM is equal to the thickness t1 of the first ultra thick metal UTM1. In particular, upper first ultra thick metal UTM1 and lower second ultra thick metal UTM2 can be accomplished by the same (design) rule for less layout constraints. Moreover, the vias V1 between the second ultra thick metal UTM2 and the first ultra thick metal UTM1 is no need to be large size. Accordingly, if three second ultra thick metal UTM2 are disposed close, those features will occupy a smaller area than that in the box 40a.

In the box 40c, the upper portion illustrates a top view of a wiring design in other embodiments of the disclosure (i.e. a X-Y plane schematic diagram), and the lower portion illustrates a cross-sectional view of the wiring design in other embodiments of the disclosure (i.e. a Y-Z plane schematic diagram). In this embodiment, the line width W3 of the second ultra thick metal UTM2 and the first ultra thick metal UTM1 is decreased to be less than the line width W2 in the box 40b. If three second ultra thick metal UTM2 are disposed close, the area occupied by those features can be further reduced and smaller than that in the box 40b of FIG. 4.

FIG. 5A is a cross-sectional view of a RF chip in accordance with some embodiments. Unless specified otherwise, like reference numerals in this embodiment represent like components in the embodiment shown in FIG. 3. Accordingly, the process steps and applicable materials may not be repeated herein.

In FIG. 5A, a RF chip 500 is provided and includes a semiconductor substrate 206, a patterned ground shield structure PGS, a radio frequency (RF) circuit 208, and a bump structure 202. The RF chip 500 may be mounted or attached onto a circuit substrate (not shown) through the bump structure 202. In some embodiments, the semiconductor substrate 206 includes a silicon substrate 502 and a semiconductor device 504 formed on the silicon substrate 502. The silicon substrate 502 may be replaced by substrate with other semiconductor materials, such as germanium; a compound semiconductor including silicon carbide, gallium arsenic, gallium phosphide, gallium nitride, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some embodiments, the semiconductor device 504 may include resistors, capacitors, inductors, diodes, or the like, and is formed in or on the substrate 502 during the front-end-of-line (FEOL) manufacturing processes. In some embodiments, a back-end-of-line (BEOL) structure 506 may be formed over the semiconductor device 504 through the BEOL manufacturing processes, and the BEOL structure 506 may include a plurality of inter-layer dielectric (ILD) layers (not shown), a plurality of metallic lines (not shown) embedded in corresponding dielectric layers, and connecting vias (not shown) therebetween. The RF circuit 208 includes a first ultra thick metals UTM1 and UTM1′ and a second ultra thick metals UTM2 and UTM2′. The patterned ground shield structure PGS is formed over the semiconductor substrate 206 and overlapped with the semiconductor device 504 in a thickness direction. In some embodiments, the patterned ground shield structure PGS may include metal lines formed of conductive materials such as aluminum, copper, titanium, titanium nitride, tantalum, tantalum nitride, tungsten, polysilicon, other suitable conductive materials, or combinations thereof. In some embodiments, an insulating material layer 508 may be formed to fill up the spaces in the patterned ground shield structure PGS; alternatively, the patterned ground shield structure PGS may be embedded in the insulating material layer 508. In some embodiments, the insulating material layer 508 may include dielectric material with low-k (LK), extreme low-k (ELK), and/or extra low-k (XLK) materials to enhance circuit performance. The dielectric material may comprise silicon nitride, silicon oxynitride, spin-on glass (SOG), undoped silicate glass (USG), fluorinated silica glass (FSG), carbon doped silicon oxide (e.g., SiCOH), carbon-containing material, polyimide, other proper porous polymeric materials, other suitable dielectric materials, and/or combinations thereof. In some embodiments, a connection structure 510 is formed between the RF circuit 208 and the patterned ground shield structure PGS, and the connection structure 510 may comprise redistribution layers, passivation layers, or the like.

Referring to FIG. 5A again, the RF circuit 208 is disposed over the patterned ground shield structure PGS, wherein the first ultra thick metals UTM1 and UTM1′ are close to the RF circuit 208, and the second ultra thick metals UTM2 and UTM2′ are disposed over the first ultra thick metals UTM1 and UTM1′. The second ultra thick metals UTM2 and UTM2′ are separated from the patterned ground shield structure PGS by a predetermined distance d. The bump structure 202 is directed formed on the second ultra thick metal UTM2. The first ultra thick metal UTM1′ and the first ultra thick metal UTM1 are the same layer with different patterns, and the second ultra thick metal UTM2′ and the second ultra thick metal UTM2 are the same layer with different patterns. In other words, the thickness t1 of the first ultra thick metal UTM1 is the same as that of the first inductor UTM1′, and the thickness t2 of the second ultra thick metal UTM2 is the same as that of the second inductor UTM2′. In some embodiments, the RF circuit 208 comprises an inductor composed of at least one of the first ultra thick metal UTM1/UTM1′ and the second ultra thick metal UTM2/UTM2. In some embodiments, the predetermined distance d between the patterned ground shield structure PGS and the second ultra thick metal UTM2/UTM2 is greater than 3 μm, for example, greater than 5 μm or greater than 10 μm. The second ultra thick metal UTM2 may be coupled to the first ultra thick metal UTM1 through a plurality of vias V1. The second ultra thick metal UTM2′ may be coupled to the first ultra thick metal UTM1′ through a plurality of vias V1′.

FIG. 5B is a perspective view of a part of the RF chip of FIG. 5A in accordance with some embodiments. In particular, the structure of FIG. 5A is flipped, and thus the patterned ground shield structure PGS is disposed over the semiconductor substrate 206 and below the first ultra thick metal UTM1′ in FIG. 5B.

Referring to FIG. 5B, the second ultra thick metal UTM2′ is an inductor and formed as a multi-coil structure. However, it is not limited thereto. In some embodiments, the second ultra thick metal UTM2′ may be formed in various configurations, which may contain a single loop or multiple loops. In some embodiments, the first ultra thick metal UTM1′ and the second ultra thick metal UTM2′ collectively form an inductor. In some embodiments, the first and second inductors UTM1′ and UTM2′ are integrated in two metal layers and are approximate from each other such that the mutual inductance is enhanced. In one example, the first and second inductors UTM1′ and UTM2′ are disposed in two approximate metal layers. Each may include metal lines in the two metal layers and vias V1′ between the two metal layers. In furtherance of the embodiment, the first coil element is configured in one metal layer and the second coil element is configured in another metal layer. The first and second ports are distributed on the two metal layers and are connected to the corresponding coil element by via features. In some embodiments, the first ultra thick metal UTM1′ is vertically aligned with and in direct contact with the second ultra thick metal UTM2′. In some embodiments, the second ultra thick metal UTM2′ is bonded over and aligned with a corresponding one of the first ultra thick metal UTM1′. In some embodiments, the via V1′ is disposed between the first ultra thick metal UTM1′ and the second ultra thick metal UTM2′.

In some embodiments, each of the first ultra thick metal UTM1′ and the second ultra thick metal UTM2′ has a coil configuration from a top view perspective. In some embodiments, the first ultra thick metal UTM1′ is a mirror or flipped pattern of the second ultra thick metal UTM2′ from the top view perspective. In some embodiments, the first ultra thick metal UTM1′ is entirely in contact with the second ultra thick metal UTM2′.

In some embodiments, each of the dielectric layer may include a dielectric material such as undoped silicate glass, a doped silicate glass, organosilicate glass, amorphous fluorinated carbon, porous variants thereof, or combinations thereof. In some embodiments, each of the first ultra thick metal UTM1′ and the second ultra thick metal UTM2′ may include at least one conductive material, which may be a combination of a metallic liner and a metallic fill material, wherein the metallic liner may include TiN, TaN, WN, TiC, TaC, and WC, and the metallic fill material may include W, Cu, Al, Co, Ru, Mo, Ta, Ti, alloys thereof, and/or combinations thereof. Other suitable metallic liner and metallic fill materials within the contemplated scope of disclosure may also be used. In one embodiment, the second ultra thick metal UTM2′ and the vias V1′ may be formed as integrated line and via structures by a dual damascene process. The first ultra thick metal UTM1′ may be electrically connected to a respective one of the semiconductor devices that are located on the semiconductor substrate 206.

The performance in an inductor defined by the Quality Factor or “Q.” The patterned ground shield structure PGS may improve the quality factor and isolation from the semiconductor substrate. In various embodiments, the patterned ground shield structure PGS may include groups of a plurality of parallel, conductive strips (fingers). In embodiments where an inductor structure (e.g. the second ultra thick metal UTM2′) is disposed over the patterned ground shield structure PGS, the patterned ground shield structure PGS may be configured so as to not impede the magnetic field surrounding the coil(s) of the inductor structure.

The patterned ground shield structure PGS is configured to include a plurality of metal lines. In some embodiments, the metal lines may be coupled together at the outer perimeter of the patterned ground shield structure PGS, and the patterned ground shield structure PGS is electrically connected to a reference voltage, e.g. the ground voltage. The patterned ground shield structure PGS may isolate the electric field generated by current flow through the inductor structure disposed over the patterned ground shield structure PGS (e.g., the second ultra thick metal UTM2′) from the semiconductor devices disposed between the patterned ground shield structure PGS and the semiconductor substrate 206. Moreover, since the patterned ground shield structure PGS is far away the second ultra thick metal UTM2′, the capacitive coupling between the second ultra thick metal UTM2′ and the patterned ground shield structure PGS may be suppressed. However, various embodiments of the present disclosure are not limited in this regard. The sizes, shapes, loop numbers, and materials of the patterned ground shield structure PGS, the first ultra thick metal UTM1′ and/or the second ultra thick metal UTM2′ may be appropriately adjusted based on product requirement.

FIGS. 6A through 6E are cross-sectional views of a process for the formation of a package structure in accordance with some embodiments.

As illustrated in FIG. 6A, a semiconductor substrate 600 is provided first. In some embodiments, a semiconductor device (not shown) may be formed in or on the semiconductor substrate 600. A BEOL structure is formed over the semiconductor substrate 600 and may cover and be connected to the semiconductor device. The BEOL structure may include an inter-layer dielectric (ILD) 602, a plurality of metallic lines 604 in the ILD 602, and connecting vias (not shown) therebetween. In some embodiments, the ILD 602 may be formed by techniques including spin-on, CVD, PVD, or atomic layer deposition (ALD). In some embodiments, the metallic lines 604 and the connecting vias may be formed in an integrated process such as a damascene process or lithography/plasma etching process.

With reference to FIG. 6B, a patterned ground shield structure PGS is formed in an insulating material layer 606 on the top 602t of the ILD 602. In some embodiments, the patterned ground shield structure PGS may include metal lines formed of conductive materials such as aluminum, copper, titanium, titanium nitride, tantalum, tantalum nitride, tungsten, polysilicon, other suitable conductive materials, or combinations thereof. In some embodiments, the insulating material layer 606 may include dielectric material with low-k, extreme low-k, and/or extra low-k materials to enhance circuit performance. The dielectric material may comprise silicon nitride, silicon oxynitride, SOG, USG, FSG, carbon doped silicon oxide (e.g., SiCOH), carbon-containing material, polyimide, other proper porous polymeric materials, other suitable dielectric materials, and/or combinations thereof. In some embodiments, the insulating material layer 606 may be formed by techniques including spin-on, CVD, PVD, or ALD. In some embodiments, the patterned ground shield structure PGS and the insulating material layer 606 may be formed in an integrated process such as a damascene process or lithography/plasma etching process.

Referring to FIG. 6C, an inter-metal dielectric (IMD) 608 and metal layers 610 embedded in the IMD 608 are formed on the top 606t of the insulating material layer 606 and the patterned ground shield structure PGS. In some embodiments, the process and the materials of the metal layers 610 and the IMD 608 may be similar to or the same as those of the metallic lines 604 and the ILD 602. However, it is not limited thereto. In some embodiments, the process and the materials of the metal layers 610 are different from those of the metallic lines 604, and the process and the materials of the IMD 608 are different from those of the ILD 602. A first ultra thick metal UTM1 is then formed on the top 608t of the IMD 608 over the Patterned ground shield structure PGS. In some embodiments, the first ultra thick metal UTM1 may be a ultra thick copper, and the method of forming the first ultra thick metal UTM1 includes depositing a dielectric layer 612, forming an opening in the dielectric layer 612, and then forming the first ultra thick metal UTM1 in the opening of the dielectric layer 612 by plating/CMP process.

Referring to FIG. 6D, a plurality of vias V1 is formed in a dielectric layer 614 on the top 612t of the dielectric layer 612 and over the first ultra thick metal UTM1. A second ultra thick metal UTM2 is formed in a dielectric layer 616 on the top 614t of the dielectric layer 614 and over the vias V1. In some embodiments, a process for forming the second ultra thick metal UTM2 is the same as a process for forming the first ultra thick metal UTM1. In some embodiments, the plurality of vias V1 and the second ultra thick metal UTM2 may be formed in an integrated process such as a damascene process. Since the thickness of the second ultra thick metal UTM2 is the same as that of the dielectric layer 616, the top 616t of the dielectric layer 616 may be coplanar with the second ultra thick metal UTM2. The first ultra thick metal UTM1 and the second ultra thick metal UTM2 may form a portion of an inductor with reference to the related descriptions of FIGS. 5A and 5B.

Referring to FIG. 6E, a passivation layer 618 is deposited on the top 616t of the dielectric layer 616 and over the second ultra thick metal UTM2, and an opening O1 is formed in the passivation layer 618 to expose a portion of the top surface S1 of the second ultra thick metal UTM2. The passivation layer 618 may be made of a dielectric material, and the dielectric material may be made of or include silicon nitride, silicon oxynitride, silicon carbide, one or more other suitable materials, or a combination thereof. The passivation layer 618 may be formed using a CVD process, a PVD process, a spin coating process, one or more other applicable processes, or a combination thereof. The opening O1 may be formed by lithography/plasma etching process. Since the top 616t of the dielectric layer 616 is coplanar with the top surface S1 of the second ultra thick metal UTM2, the passivation layer 618 may have a flat topography, i.e. the top 618t of the passivation layer 618 is a flat surface. In some embodiments, a polymer dielectric layer 620 is formed over the passivation layer 620 and the second ultra thick metal UTM2, and then another opening O2 is formed in the polymer dielectric layer 620 to expose the portion of the top surface S1 of the second ultra thick metal UTM2. The polymer dielectric layer 620 may be made of or include an organic material. The organic material may include polyimide (PI), polybenzoxazole (PBO), benzocyclobutene (BCB), one or more other suitable materials, or a combination thereof. The organic material may be photosensitive. The polymer dielectric layer 620 may be formed using a CVD process, a PVD process, a spin coating process, one or more other applicable processes, or a combination thereof. The opening O2 may be formed by lithography/plasma etching process, and the opening O2 may overlap with the opening O1. Since the top 618t of the passivation layer 618 is a flat surface, the polymer dielectric layer 620 may have a flat topography, i.e. the top 620t of the polymer dielectric layer 620 is also a flat surface.

Referring to FIG. 6E again, a conductive connector 624 is formed on the portion of the top surface S1 of the second ultra thick metal UTM2. The conductive connector 624 may be ball grid array (BGA) bump structures, solder balls, metal pillars, controlled collapse chip connection (C4) bumps, micro bumps, electroless nickel-electroless palladium-immersion gold technique (ENEPIG) formed bumps, or the like. The conductive connector 624 may include a conductive material such as solder, copper, aluminum, gold, nickel, silver, palladium, tin, the like, or a combination thereof. For example, the conductive connector 624 is a copper bump, and the copper bump is in direct contact with the second ultra thick metal UTM2. In some embodiments, the conductive connector 624 is formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connector 624 comprises metal pillars (such as copper pillars) formed by a sputtering, printing, electro plating, electroless plating, CVD, or the like. The metal pillars may be solder free and have substantially vertical sidewalls. In some embodiments, a metal cap layer 626 is formed on the top of the conductive connector 624 to form a bump structure 622 directly on the second ultra thick metal UTM2. The metal cap layer 626 may include nickel, tin, tin-lead, gold, silver, palladium, indium, nickel-palladium-gold, nickel-gold, the like, or a combination thereof and may be formed by a plating process.

According to some embodiments, a package structure includes a semiconductor substrate, a first ultra thick metal (UTM), a second ultra thick metal, and a bump structure. The first ultra thick metal is disposed over the semiconductor substrate. The second ultra thick metal is disposed over and coupled to the first ultra thick metal. The bump structure is directly disposed on the second ultra thick metal.

According to some embodiments, a package structure includes a semiconductor substrate with a semiconductor device, a patterned ground shield (PGS) structure, a radio frequency (RF) circuit, and a bump structure. The PGS structure is formed over the semiconductor substrate and overlapped with the semiconductor device in a thickness direction. The RF circuit is disposed over the PGS structure, wherein the RF circuit includes a first ultra thick metal (UTM) close to the PGS structure and a second ultra thick metal disposed over the first ultra thick metal. The second ultra thick metal is separated from the PGS structure by a predetermined distance. The bump structure is directed formed on the second ultra thick metal.

According to some embodiments, a method of forming a package structure includes providing a semiconductor substrate with a semiconductor device, forming a patterned ground shield (PGS) structure over the semiconductor device of the semiconductor substrate, forming a first ultra thick metal (UTM) over the PGS structure, forming a second ultra thick metal over the first ultra thick metal, and forming a bump structure directly on the second ultra thick metal.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a semiconductor substrate;
a first ultra thick metal (UTM) disposed over the semiconductor substrate;
a second ultra thick metal disposed over and coupled to the first ultra thick metal; and
a bump structure directly disposed on the second ultra thick metal.

2. The package structure of claim 1, wherein a thickness of the first ultra thick metal is greater than 3 μm, and a thickness of the second ultra thick metal is greater than 3 μm.

3. The package structure of claim 1, wherein at least one of the first ultra thick metal and the second ultra thick metal forms a portion of an inductor.

4. The package structure of claim 1, wherein the bump structure comprises a copper bump, and the copper bump is in direct contact with the second ultra thick metal.

5. The package structure of claim 1, further comprising a patterned ground shield (PGS) structure disposed between the semiconductor substrate and the first ultra thick metal.

6. The package structure of claim 1, further comprising a polymer dielectric layer over the second ultra thick metal, and the bump structure passes through the polymer dielectric layer to connect with the second ultra thick metal.

7. The package structure of claim 6, wherein a top surface of the polymer dielectric layer is a flat surface.

8. A package structure, comprising:
a semiconductor substrate with a semiconductor device;
a patterned ground shield (PGS) structure formed over the semiconductor substrate and overlapped with the semiconductor device in a thickness direction;
a radio frequency (RF) circuit disposed over the PGS structure, wherein the RF circuit comprises a first ultra thick metal (UTM) close to the PGS structure and a second ultra thick metal disposed over the first ultra thick metal and separated from the PGS structure by a predetermined distance; and
a bump structure directed formed on the second ultra thick metal.

9. The package structure of claim 8, wherein a thickness of the first ultra thick metal is greater than 3 μm, and a thickness of the second ultra thick metal is greater than 3 μm.

10. The package structure of claim 8, wherein the RF circuit comprises an inductor composed of at least one of the first ultra thick metal and the second ultra thick metal.

11. The package structure of claim 8, wherein the bump structure comprises a copper bump, and the copper bump is in direct contact with the second ultra thick metal.

12. The package structure of claim 8, wherein the predetermined distance between the PGS structure and the second ultra thick metal is greater than 3 μm.

13. The package structure of claim 8, wherein the second ultra thick metal is coupled to the first ultra thick metal.

14. A method of forming a package structure, comprising:
providing a semiconductor substrate with a semiconductor device;
forming a patterned ground shield (PGS) structure over the semiconductor device of the semiconductor substrate;
forming a first ultra thick metal (UTM) over the PGS structure;
forming a second ultra thick metal over the first ultra thick metal; and
forming a bump structure on the second ultra thick metal.

15. The method of forming a package structure of claim 14, wherein a process for forming the second ultra thick metal is the same as a process for forming the first ultra thick metal.

16. The method of forming a package structure of claim 14, wherein after forming the second ultra thick metal further comprises:
depositing a passivation layer over the second ultra thick metal; and
forming an opening in the passivation layer to expose a portion of a top surface of the second ultra thick metal.

17. The method of forming a package structure of claim 16, wherein steps of forming the bump structure comprises:
forming a polymer dielectric layer over the passivation layer and the second ultra thick metal;
forming an opening in the polymer dielectric layer to expose the portion of the top surface of the second ultra thick metal; and
plating a conductive connector directly on the portion of the top surface of the second ultra thick metal.

18. The method of forming a package structure of claim 17, wherein a thickness of the polymer dielectric layer is less than that of the second ultra thick metal.

19. The method of forming a package structure of claim 14, wherein before forming the second ultra thick metal further comprises forming a plurality of vias on the first ultra thick metal.

20. The method of forming a package structure of claim 14, wherein at least one of the first ultra thick metal and the second ultra thick metal forms a portion of an inductor.
